(19) United States
(12) Patent Application Publication
(10) Pub. No.: US 2006/0139862 A1
(43) Pub. Date: Jun. 29, 2006

(54) Hinged electronic device with hinged screen

(76) Inventors: Yajun Wang, Buffalo Grove, IL (US); Daniel K. Elliott, Coral Springs, FL (US); David W. Trahan, Grayslake, IL (US)

Correspondence Address: MOTOROLA INC, 600 NORTH US HIGHWAY 45, ROOM AS437, LIBERTYVILLE, IL, 60048-5343, US

(21) Appl. No.: 11/021,297

(22) Filed: Dec. 23, 2004

(51) Int. Cl. G06F 1/16; H05K 5/00

(52) U.S. Cl. 361/681

(57) ABSTRACT

A hinged electronic device (100) includes housing hinge mechanism (130) holding together a first housing section (110) with a first screen portion (160) of a hinged screen (150) and a second housing section (120) with a recess (184) for a second screen portion (170) of the hinged screen (150). The first screen portion (160) and the second screen portion (170) are held together by a screen hinge mechanism (480). When the hinged electronic device (100) is closed, the hinged screen (150) is in a stowed position. When the hinged electronic device (100) is fully opened, the hinged screen (150) is in a fully deployed position, which has the first screen portion (160) and the second screen portion (170) within a single plane.

### FIELD OF THE DISCLOSURE

This disclosure relates to screens for use in electronic devices.

### BACKGROUND OF THE DISCLOSURE

Certain electronic devices have two housing sections connected by a hinge. Examples of hinged electronic devices include laptop computers, portable DVD and videodisc players, and certain mobile phones. One housing section usually includes a display while the other housing section usually includes a keypad. As electronic devices get smaller, the areas available for the display and keypad also get smaller. Meanwhile, electronic device services such as text messaging and electronic mail, word processing, multimedia graphics, and Internet access increase the demand for a larger display size, greater display resolution, and higher color quality displays.

Thus, there is an opportunity for increasing display size, display resolution, and display color quality in a hinged electronic device. The various aspects, features and advantages of the disclosure will become more fully apparent to those having ordinary skill in the art upon careful consideration of the following Drawings and accompanying Detailed Description.

### BRIEF DESCRIPTION OF THE DRAWINGS

FIG. 1 shows a perspective view of a hinged electronic device with a fully deployed hinged screen in accordance with a first embodiment.

FIG. 2 shows a perspective view of the hinged electronic device shown in FIG. 1 with a partially deployed hinged screen.

FIG. 3 shows a perspective view of the hinged electronic device shown in FIG. 1 with a stowed hinged screen.

FIG. 4 shows an exploded view of the hinged electronic device with a hinged screen in accordance with the first embodiment.

FIG. 5 shows a cross-section view of a hinged electronic device with a fully deployed hinged screen in accordance with the first embodiment.

FIG. 6 shows a cross-section view of a hinged electronic device with a partially deployed hinged screen in accordance with the first embodiment.

FIG. 7 shows a cross-section view of a hinged electronic device with a stowed hinged screen in accordance with the first embodiment.

### DETAILED DESCRIPTION

A hinged electronic device includes a housing hinge mechanism holding together a first housing section with a first screen portion of a hinged screen and a second housing section with a recess for a second screen portion of the hinged screen. The first screen portion and the second screen portion are held together by a screen hinge mechanism. When the hinged electronic device is closed, the hinged screen is in a stowed position. When the hinged electronic device is fully opened, the hinged screen is in a fully deployed position, which has the first screen portion and the second screen portion within a single plane. When the hinged screen is fully deployed a single display controller can show a single image across both screen portions. Alternately, a first display controller can show an image on the first screen portion and a second display controller can show an image on the second screen portion.

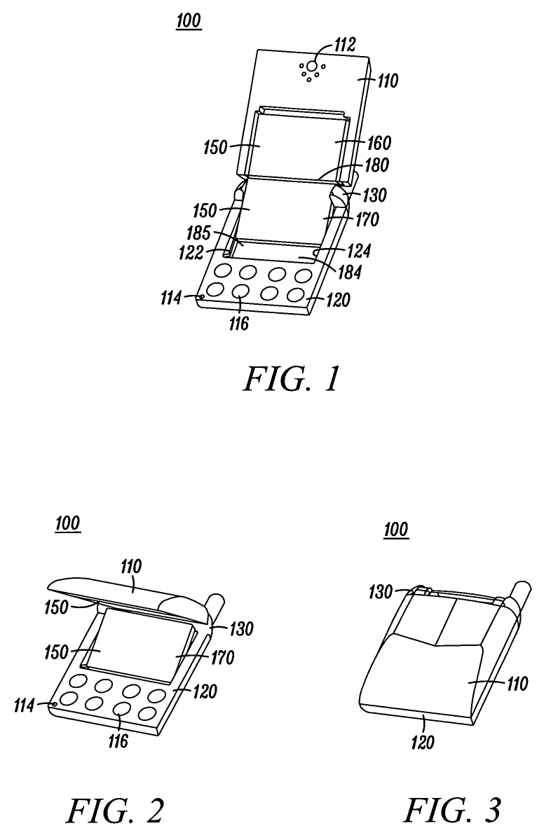

FIG. 1 shows a perspective view of a hinged electronic device 100 with a fully deployed hinged screen 150 in accordance with a first embodiment, FIG. 2 shows a perspective view of the hinged electronic device 100 shown in FIG. 1 with a partially deployed hinged screen 150, and FIG. 3 shows a perspective view of the hinged electronic device 100 shown in FIG. 1 with a stowed hinged screen (not visible). The embodiment shown has a mobile telephone as the hinged electronic device 100; however, this disclosure can be applied to other electronic devices such as laptop computers, personal digital assistants (PDAs), portable DVD and videodisc players, portable electronic video games, remote controllers, electronic calculators, and the like. Some electronic devices, such as portable electronic video games and remote controllers, do not generally have hinges; however, hinges can be added in accordance with this disclosure. Hinged electronic devices are useful not only for portability but also for stowability. In other words, hinges may also be applied to electronic devices for the purpose of making the electronic devices easier to store without necessarily seeking to make the electronic devices easier to transport.

When deployed, the hinged screen 150 provides a single planar display screen that can be controlled by a conventional display controller. Alternately, the display controller can be a multi-screen display controller designed to split a single image over multiple screens. Depending on the capability of the conventional display controller and the limitations of the perimeter of the first screen portion 160 and the second screen portion 170, there may be a slight discontinuity of a displayed image from the first screen portion 160 and the second screen portion 170 of the hinged screen 150. Nonetheless, by using a hinged screen 150, the display screen can be larger than conventional display screens in hinged electronic devices, which are constrained by joints in the housing of the hinged electronic device 100. Alternately, the first screen portion 160 can be controlled by a first display controller and the second screen portion 170 can be controlled by a second display controller. This alternate embodiment allows a user to easily view two independent images.

When the hinged electronic device 100 is opened, the second screen portion 170 of the hinged screen 150 moves from a stowed position in a recess 184 of the second housing portion 120 to a fully deployed position that is planar with the first screen portion 160. In order to keep the second screen portion 170 properly aligned with the first screen portion 160 through this transition, a first track 122 is provided in a first side of the recess 184. A second track 124 (not visible), parallel to the first track 122, is similarly situated in an opposing second side of the recess 184. The tracks can be implemented as a rail, a groove, or another type of guide. The first track 122 and second track 124 are bent to provide proper positioning for the second screen portion 170 when in the fully deployed position (FIG. 1) and the stowed position (FIG. 3) and also provide a smooth action during movement through the partially deployed positions (FIG. 2).

When the second screen portion 170 is not in the stowed position, the bottom surface 185 of the recess 184 may reveal a touchpad, soft keys, or other user input device.

The hinged electronic device 100 has a first housing section 110 and a second housing section 120 rotatably held together by a housing hinge mechanism 130. The first housing section 110 includes a loudspeaker port 112 and a first screen portion 160 of the hinged screen 150. The second housing section 120 includes a keypad 116, a microphone port 114, and a recess 184 for the second screen portion 170 of the hinged screen 150. Depending on the implementation of the hinged electronic device 100, the loudspeaker port 112, the keypad 116, and/or the microphone port 114 can be eliminated or located to different areas of the hinged electronic device 100.

Distributed within the first housing section 110 and the second housing section 120 are electronic elements for the hinged electronic device 100. For this mobile telephone embodiment, an antenna, a loudspeaker, a microphone, keypad components, radio frequency circuitry, baseband circuitry, various processors, and several memory elements are housed within the first housing section 110 and the second housing section 120. Connections between electronic elements in the first housing section 110 and the second housing section 120 are made using flexible connection circuitry (not shown) guided through the housing hinge mechanism 130.

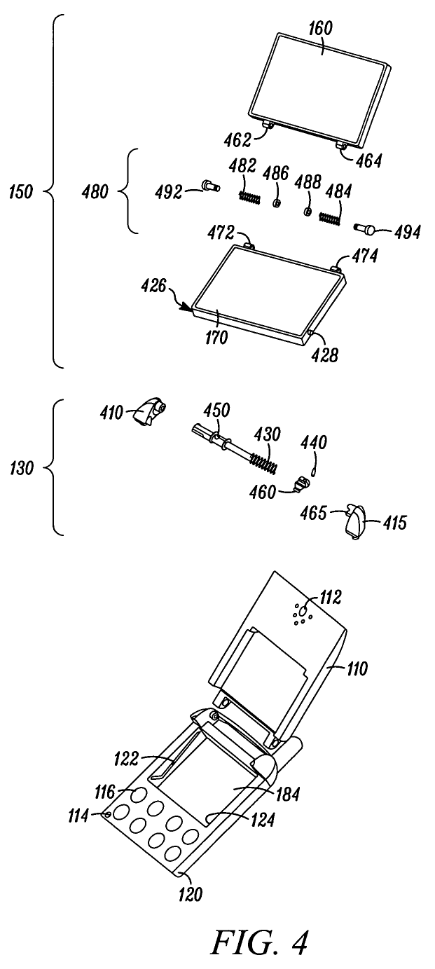

FIG. 4 shows an exploded view of the hinged electronic device 100 with a hinged screen 150 in accordance with the first embodiment. In this embodiment, the housing hinge mechanism 130 is an active hinge. When the first housing section 110 and the second housing section 120 are opened partially, the active hinge provides force to assist the hinged electronic device 100 to open fully. Although one skilled in the art would be familiar with active hinges, a spring-loaded pin-and-barrel hinge is generally described here. In this embodiment, the housing hinge mechanism 130 has a pair of barrels 410, 415 (sometimes called “knuckles”) as part of the second housing section 120. A shaft 450 and a spring 430 are positioned between the barrels 410 and 415. A cam 460 at one end of the shaft 450 engages with a cam follower 465 fastened to one barrel 415 using a pin 440.

Due to the geometries of the cam 460 and cam follower 465, and the energy provided by the spring 430 along the shaft 450, a partial opening of the active housing hinge mechanism 130 (beyond a first predetermined angle) provides enough force to cause the hinged electronic device 100 to open fully. Conversely, a partial closing of the active housing hinge mechanism 130 (beyond a second predetermined angle) causes the hinged electronic device 100 to close fully. The first predetermined angle and the second predetermined angle can be the same. Alternate active and passive hinge mechanisms can be substituted for the active housing hinge mechanism described above.

In this embodiment, the screen hinge mechanism 480 is a passive hinge which follows the active hinge of the housing hinge mechanism 130. When the housing hinge mechanism 130 opens, the screen hinge mechanism 480 automatically opens to deploy the hinged screen 150. Conversely, when the housing hinge mechanism 130 closes, the screen hinge mechanism 480 automatically closes to stow the hinged screen 150. Although one skilled in the art would be familiar with passive hinges, a passive hinge is generally described here. A first barrel 462 and a second barrel 464 are on a lower edge of the first screen portion 160. A third barrel 472 and a fourth barrel 474 are on an upper edge of the second screen portion 170. When the lower edge of the first screen portion 160 and the upper edge of the second screen portion 170 are adjacent, the first barrel 462 and the third barrel 472 are side-by-side, and the second barrel 464 and the fourth barrel 474 are side-by-side. A first pin 492 and first spring 482 goes through the first barrel 462 and the third barrel 472, and they are held in place by a first snap ring 486. Similarly, a second pin 494 and a second spring 484 goes through the second barrel 464 and the fourth barrel 474, and they are held in place by a second snap ring 488. Alternate active and passive hinge mechanisms can be substituted for the simple pin-and-barrel passive screen hinge mechanism described above.

Because the housing hinge mechanism 130 in this embodiment is an active hinge and the screen hinge mechanism 480 is a passive hinge, when the hinged electronic device 100 is partially opened, force from the active hinge causes the posts 426, 428 of the second screen portion 170 to move along the tracks 122, 124 in the recess 184 from a stowed position to a fully deployed position. In an alternate embodiment, both the housing hinge mechanism 130 and the screen hinge mechanism 480 are passive hinges, which simply means that a user must provide all the force needed to open the hinged electronic device 100 and deploy the hinged screen 150. In yet another embodiment, both housing hinge mechanism 130 and the screen hinge mechanism 480 are active hinges. In a further embodiment, the housing hinge mechanism 130 is passive while the screen hinge mechanism 480 is active.

The first housing section 110 fixedly holds the first screen portion 160, which is rotatably coupled to the second screen portion 170 by the screen hinge mechanism 180. The second screen portion 170 has a first post 426 (not visible) and a second post 428 opposite the first post 426. The first post 426 engages with the first track 122 in one side of the recess 184 of the second housing portion 120, and the second post 428 engages with the second track 124 (not visible) in the opposing side of the recess 184, to guide the second screen portion 170 within the recess 184 as it deploys and stows.

Flexible connection circuitry (not shown) electrically couples the second screen portion 170 to the first screen portion 160. When the hinged screen 150 is deployed, the first screen portion 160 and the second screen portion 170 act as a single planar display according to the first embodiment. In an alternate embodiment, the first screen portion 160 may display an image independent of the second screen portion 170.

In the first embodiment, the first screen portion 160 and the second screen portion 170 of the hinged screen 150 are each a quarter video graphics adapter (QVGA) resolution display of 320×240 pixels. Thus, the two portions combined make a half video graphics adapter (HVGA) resolution display of 640×240 pixels. As display technology improves to allow higher-resolution screens in smaller sizes, the first portion 160 and the second portion 170 of the hinged screen 150 could each be a HVGA resolution display and thus combined to make a full VGA resolution display of 640×480 pixels. By concatenating two VGA-quality display screens, the hinged screen 150 provides a single large size, high resolution, and high color quality display within a hinged electronic device 100. Alternate embodiments can replace one or more of the screen portions with other types of screens, such as a touch screen or combination touch and display screen.

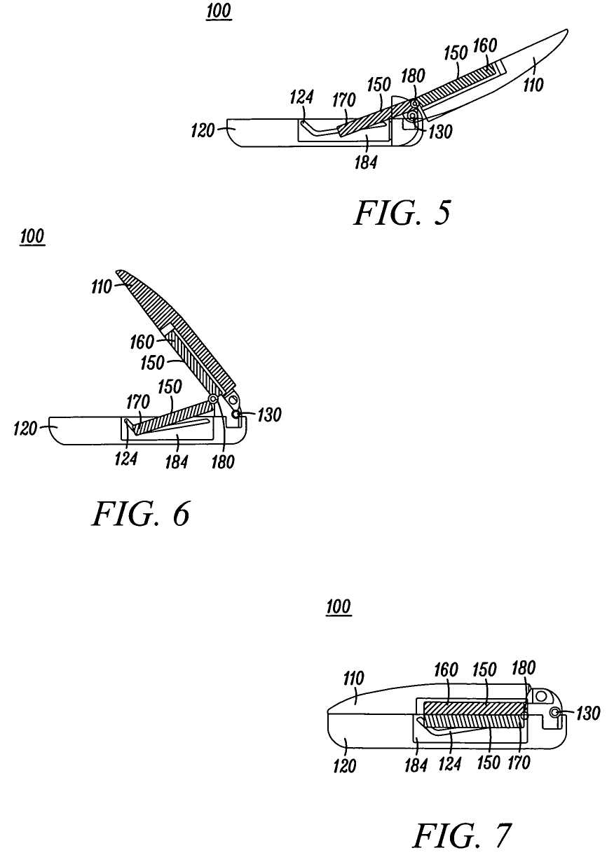

FIG. 5 shows a cross-section view of a hinged electronic device 100 with a fully deployed hinged screen 150 in accordance with the first embodiment, FIG. 6 shows a cross-section view of a hinged electronic device 100 with a partially deployed hinged screen 150 in accordance with the first embodiment, and FIG. 7 shows a cross-section view of a hinged electronic device 100 with a stowed hinged screen 150 in accordance with the first embodiment. In these cross-section views, the second track 124 is shown, which was not visible in the various perspective and exploded views. When the hinged electronic device 100 is in a closed position, the hinged screen 150 is protected within the first housing section 110 and the second housing section 120. When the hinged electronic device 100 is in a closed position, the second screen portion 170 of the hinged screen 150 is stowed within the recess 184 of the second housing section 120.

Thus, a hinged electronic device with hinged screen provides a display screen that is not limited by the size of a housing section on one side of a housing hinge mechanism. The hinged electronic device has a small size when folded and a hinged screen that automatically deploys when the hinged electronic device is opened. A hinged display screen allows for larger displays, higher resolution displays, and colored displays. The hinged display screen can be controlled by a display controller as a single display or as two independent displays.

While this disclosure includes what are considered presently to be the preferred embodiments and best modes of the invention described in a manner that establishes possession thereof by the inventors and that enables those of ordinary skill in the art to make and use the invention, it will be understood and appreciated that there are many equivalents to the preferred embodiments disclosed herein and that modifications and variations may be made without departing from the scope and spirit of the invention, which are to be limited not by the preferred embodiments but by the appended claims, including any amendments made during the pendency of this application and all equivalents of those claims as issued. It is further understood that the use of relational terms such as first and second, top and bottom, and the like, if any, are used solely to distinguish one from another entity, item, or action without necessarily requiring or implying any actual such relationship or order between such entities, items or actions.

We claim:

1. A hinged electronic device comprising:
a first housing section with a first screen portion;
a housing hinge mechanism coupled to the first housing section;
a second housing section with a recess for a second screen portion, coupled to the housing hinge mechanism; and
a screen hinge mechanism coupled to the first screen portion and the second screen portion.

2. A hinged electronic device in accordance with claim 1, where the second screen portion stows in the recess when the first housing section and the second housing section are in a closed position.

3. A hinged electronic device in accordance with claim 1, further comprising:
a post, coupled to the second screen portion; and
a corresponding track in the recess.

4. A hinged electronic device in accordance with claim 1, wherein the first screen portion is a display screen.

5. A hinged electronic device in accordance with claim 4, wherein the second screen portion is a display screen.

6. A hinged electronic device in accordance with claim 5, further comprising:
a display controller for providing a single image on the first screen portion and the second screen portion.

7. A hinged electronic device in accordance with claim 5, further comprising:
a first display controller for providing a first image on the first screen portion.

8. A hinged electronic device in accordance with claim 7, further comprising:
a second display controller for providing a second image on the second screen portion.

9. A hinged electronic device in accordance with claim 1, wherein a wall of the recess has a user input device.

10. A hinged electronic device in accordance with claim 1, wherein the housing hinge mechanism is an active hinge.

11. A hinged electronic device in accordance with claim 10, wherein the screen hinge mechanism is a passive hinge.

12. A hinged electronic device in accordance with claim 1, wherein the screen hinge mechanism is a passive hinge.

13. A hinged electronic device comprising:
a first housing section with a first screen portion;
a second housing section with a recess, moveably coupled to the first housing section; and
a second screen portion continually positioned at least partially within the recess, moveably coupled to the first screen portion.

14. A hinged electronic device in accordance with claim 13, wherein the second housing section is rotatably coupled to the first housing section.

15. A hinged electronic device in accordance with claim 13, wherein the second screen portion is rotatably coupled to the first screen portion.
